(19) United States
(12) Patent Application Publication
(10) Pub. No.: US 2013/0200387 A1
(43) Pub. Date: Aug. 8, 2013

(54) NITRIDE BASED HETEROJUNCTION SEMICONDUCTOR DEVICE AND MANUFACTURING METHOD THEREOF

(71) Applicant: SAMSUNG ELECTRONICS CO., LTD., Suwon-si (KR)

(72) Inventors: Jae Hoon LEE, Gyeonggi-do (KR); Ki Se KIM, Gyeonggi-do (KR)

(73) Assignee: SAMSUNG ELECTRONICS CO., LTD., Suwon-si (KR)

(21) Appl. No.: 13/757,933

(22) Filed: Feb. 4, 2013

(30) Foreign Application Priority Data
Feb. 6, 2012 (KR) 10-2012-0011864

(51) Int. Cl. H01L 29/20; H01L 29/66

(52) U.S. Cl. CPC H01L 29/2003; H01L 29/66431
USPC 257/76; 438/172

(57) ABSTRACT

A nitride based heterojunction semiconductor device includes a GaN layer on a substrate, an Al-doped GaN layer on the GaN layer, an AlGaN layer on the Al-doped GaN layer, a source electrode, a gate electrode, and a drain electrode on the AlGaN layer, a first field plate on the AlGaN layer, the first field plate being in contact with the gate electrode, and a second field plate on the AlGaN layer, the second field plate being separated from the first field plate by a distance.

### CROSS-REFERENCE TO RELATED APPLICATION

The present application claims priority under 35 U.S.C. §119 to Korean Patent Application No. 10-2012-0011864, filed on Feb. 6, 2012, in the Korean Intellectual Property Office, and entitled: “Nitride Based Heterojunction Semiconductor Device and Manufacturing Method Thereof,” which is incorporated by reference herein in its entirety.

### BACKGROUND

1. Field

Embodiments relate to a nitride based heterojunction semiconductor device, and a method of manufacturing the nitride based heterojunction semiconductor device.

2. Description of the Related Art

With rapid development in the information and communications industry, demand for wireless communication technologies, for example, personal mobile communication, wideband communication, military radar, and the like, is gradually increasing. Accordingly, there is a growing need for a high output and high frequency device with a high level of information processing technology.

### SUMMARY

Embodiments are directed to a nitride based heterojunction semiconductor device, including a GaN layer on a substrate, an Al-doped GaN layer on the GaN layer, an AlGaN layer on the Al-doped GaN layer, a source electrode, a gate electrode, and a drain electrode on the AlGaN layer, a first field plate on the AlGaN layer, the first field plate being in contact with the gate electrode, and a second field plate on the AlGaN layer, the second field plate being separated from the first field plate by a distance.

The first field plate and the second field plate may have a superlattice structure in which a p-type AlGaN layer and a p-type GaN layer are laminated alternately.

The AlGaN layer may include an etched area at a position in which the gate electrode is located.

The semiconductor device may further include a gate insulating layer between the etched area and the gate electrode.

A sidewall of the etched area and a sidewall of the first field plate may be aligned.

The semiconductor device may further include a passivation layer on the

AlGaN layer, the passivation layer exposing the source electrode, the gate electrode, and the drain electrode.

The GaN layer may be a semi-insulating high-resistance GaN layer.

The first field plate may be between the AlGaN layer and the gate electrode, and the second field plate may be between the first field plate and the drain electrode.

A content of Al in the Al-doped GaN layer may be less than or equal to about 1 at. %.

Embodiments are also directed to a nitride based heterojunction semiconductor device, including a GaN layer on a substrate, an Al-doped GaN layer on the GaN layer, an AlGaN layer on the Al-doped GaN layer, a Schottky electrode and an ohmic electrode on the AlGaN layer, a first field plate on the AlGaN layer, the first field plate being in contact with the Schottky electrode, and a second field plate on the AlGaN layer, the second field plate being separated from the first field plate by a distance.

The first field plate and the second field plate may have a superlattice structure in which a p-type AlGaN layer and a p-type GaN layer are laminated alternately.

The first field plate may be between the Schottky electrode and the ohmic electrode, and the second field plate may be between the first field plate and the ohmic electrode.

Embodiments are also directed to a method of manufacturing a nitride based heterojunction semiconductor device, the method including forming a GaN layer, an Al-doped GaN layer, and an AlGaN layer on a substrate, sequentially, depositing an insulating layer on the AlGaN layer, forming, in the insulating layer, a first via-hole and a second via-hole to expose the AlGaN layer, the second via-hole being separated from the first via-hole by a distance, forming a first field plate and a second field plate on the AlGaN layer that is exposed through the first via-hole and the second via-hole, removing the insulating layer from the AlGaN layer, and forming, on the AlGaN layer, a first electrode that is separated from the first field plate and the second field plate, and forming, on the AlGaN layer, a second electrode that is in contact with the first field plate.

Forming the first field plate and the second field plate may include regrowing the AlGaN layer.

The first field plate and the second field plate may have a superlattice structure in which a p-type AlGaN layer and a p-type GaN layer are laminated alternately.

The method may further include forming, on the AlGaN layer, a third electrode that is separated from the first field plate and the second field plate. The first electrode may be a source electrode, the second electrode may be a gate electrode, and the third electrode may be a drain electrode.

The method may further include forming an etched area on the AlGaN layer; and forming a gate insulating layer in the etched area.

The method may further include forming, on the AlGaN layer, a passivation layer to expose the source electrode, the gate electrode, and the drain electrode.

Forming the first via-hole and the second via-hole may include forming the first via-hole in a first area in which the gate electrode is to be formed, and forming the second via-hole between the first via-hole and a second area in which the drain electrode is to be formed.

The first electrode may be an ohmic electrode, and the second electrode may be a Schottky electrode.

### BRIEF DESCRIPTION OF THE DRAWINGS

Features will become apparent to those of skill in the art by describing in detail exemplary embodiments with reference to the attached drawings in which:

FIG. 1 illustrates a cross-sectional view of an exemplary structure of a nitride based heterojunction semiconductor device according to an embodiment;

FIG. 2 illustrates a cross-sectional view of an exemplary structure of a nitride based heterojunction semiconductor device according to an embodiment;

FIGS. 3 through 8 illustrate cross-sectional views of stages in an exemplary method of manufacturing a nitride based heterojunction semiconductor device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, a region illustrated as a rectangle may have rounded or curved features and the boundary between that region and another region may be a gradient rather than a binary change from the one region to the other region. Additionally, the labels provided in the figures are exemplary and are not intended to limit the scope of the embodiments. Thus, the figures are schematic in nature and are not intended to limit the scope of the embodiments.

Terminologies used herein are defined to appropriately describe the exemplary embodiments and thus may be changed depending on a user, the intent of an operator, or a custom. Accordingly, the terminologies should be interpreted based on the following overall description as understood by those of skill in the art.

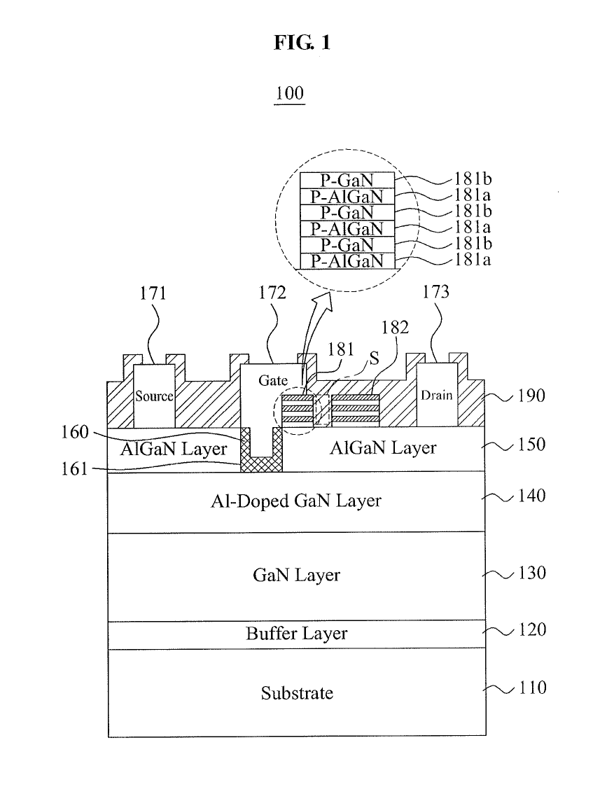

FIG. 1 illustrates a cross-sectional view of an exemplary structure of a nitride based heterojunction semiconductor device 100 according to an embodiment. The semiconductor device 100 may correspond to, e.g., a normally OFF type of nitride based heterojunction field effect transistor, including a substrate 110, a buffer layer 120, a gallium nitride (GaN) layer 130, an aluminum (Al)-doped GaN layer 140, an aluminum gallium nitride (AlGaN) layer 150, a source electrode 171, a gate electrode 172, a drain electrode 173, a first field plate 181, and a second field plate 182.

The buffer layer 120 may be formed on the substrate 110. The substrate 110 may correspond to a sapphire substrate, but may be a suitable substrate, and may correspond to a substrate for growing nitride, for example, a silicon carbide (SiC) substrate, a nitride substrate, and the like. The buffer layer 120 may correspond to an aluminum nitride (AlN) or GaN based nitride layer grown at a low temperature, which may be suitably used for a buffer layer.

The GaN layer 130 may be formed on the buffer layer 120. The GaN layer 130 may correspond to a semi-insulating GaN layer and/or a high resistance GaN layer. The GaN layer 130 may be grown at a low temperature, and may then be grown at a high temperature. In this instance, the low temperature growth and the high temperature growth may be performed successively. For example, the GaN layer 130 may be primarily grown at a temperature ranging from about 800° C. to about 950° C., and thus may secure a high resistance, and may be secondarily grown at an increased temperature from about 1,000° C. to about 1,100° C., and thus a single crystal may be grown (e.g., the GaN layer 130 may be single crystalline).

The Al-doped GaN layer 140 may be formed on the GaN layer 130. The Al-doped GaN layer 140 may improve crystallinity, and may improve an electrical property of a transistor. By passivating a Ga vacancy corresponding to a defect generated by doping with Al, a growth to a two-dimensional or three dimensional dislocation may be substantially inhibited, and the Al-doped GaN layer 140 may have excellent crystallinity. Accordingly, the Al-doped GaN layer 140 may block low crystallinity from the GaN layer 130, that is, the semi-insulating and/or high resistance GaN layer, and may enable excellent crystal growth. Here, a content of Al to be doped may be, e.g., less than or equal to about 1% (i.e., may not exceed about 1%). A content of Al to be doped may correspond to about 0.1% to about 1%, about 0.3% to about 0.6%, or about 0.45%, (e.g., atomic %) and thus crystallinity may be improved.

The Al-doped GaN layer 140 may have a thickness of about 0.1 to about 1 micrometer (μm). When the Al-doped GaN layer 140 has a thickness within the above range, growth may be increased, crystallinity may be improved, and a size of an element may not be overly increased (e.g., beyond the effect of crystallinity improvement).

The AlGaN layer 150 may be formed on the Al-doped GaN layer 140. A two-dimensional electron gas (2-DEG) layer (not shown) may be formed on an interface of the AJGaN layer 150 and the Al-doped GaN layer 140, e.g., due to discontinuity of a conduction band.

The source electrode 171, the gate electrode 172, and the drain electrode 173 may be formed on the AlGaN layer 150. Also, the first field plate 181 and the second field plate 182 may be fondled on the AlGaN layer 150.

The AlGaN layer 150 may include an etched area 161 at a position in which the gate electrode 172 is formed. A gate insulating layer 160 may be formed between the etched area 161 and the gate electrode 172.

The first field plate 181 may be formed between the gate electrode 172 and the drain electrode 173, and may be formed to be in contact with the gate electrode 172. The second field plate 182 may be formed between the first field plate 181 and the drain electrode 173, and may be separated from the first field plate 181 by a first distance S.

Referring to a partially enlarged view of the first field plate 181, the first field plate 181 may have a superlattice structure in which a p-type AlGaN layer 181a and a p-type GaN layer 181b are laminated alternately. The number of the p-type AlGaN layers 181a and the p-type GaN layers 181b may be a suitable number, e.g., a number different from the number of layers illustrated in FIG. 1. The second field plate 183 may also have a superlattice structure in which a p-type AlGaN layer and a p-type GaN layer are laminated alternately, similar to the first field plate 181.

The first field plate 181, the first space S, and the second field plate 182 may distribute an electric field applied to the gate electrode 172, and may substantially prevent and/or reduce the electrode field from being concentrated on the gate electrode 172. That is, an electric field that may be concentrated at a corner of the gate electrode 172 may be distributed through three areas of the first plate 181, the first space S, and the second field plate 182. Accordingly, a leakage current occurring when the transistor is operated may be reduced, and a breakdown voltage may be increased.

The passivation layer 190 may be formed on the AlGaN layer 150 to expose the source electrode 171, the gate electrode 172, and the drain electrode 173. Although a structure of the normally OFF type of nitride based heterojunction field effect transistor has been described with reference to FIG. 1, a first field plate and a second field plate may be included in a normally ON type of nitride based heterojunction field effect transistor to distribute an electric field to be applied to a gate electrode.

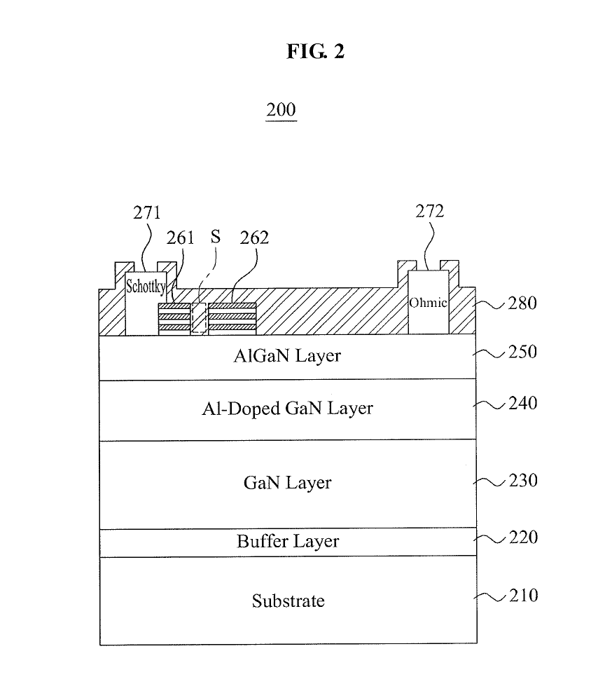

FIG. 2 illustrates a cross-sectional view of an exemplary structure of a nitride based heterojunction semiconductor device 200 according to an embodiment. The semiconductor device 200 may correspond to a nitride based heterojunction Schottky diode, including a substrate 210, a buffer layer 220, a GaN layer 230, an Al-doped GaN layer 240, an AlGaN layer 250, a first field plate 261, a second field plate 262, a Schottky electrode 271, an ohmic electrode 272, and a passivation layer 280.

The substrate 210, the buffer layer 220, the GaN layer 230, and the Al-doped GaN layer 240 of FIG. 2 may be structurally identical to the substrate 110, the buffer layer 120, the GaN layer 130, and the Al-doped GaN layer 240 of FIG. 1, and further description thereof will not be duplicated.

The buffer layer 220 may correspond to an AN or GaN based nitride layer that may be grown on the substrate 210 at a low temperature. The GaN layer 230 may be formed on the buffer layer 220, and may correspond to a semi-insulating and/or high resistance GaN layer.

The Al-doped GaN layer 240 may be formed on the GaN layer 230. The AlGaN layer 250 may be formed on the Al-doped GaN layer 240. A 2-DEG layer (not shown) may be formed on an interface of the AlGaN layer 250 and the Al-doped GaN layer 240, e.g., due to discontinuity of a conduction band.

The first field plate 261 may be formed on the AlGaN layer 250. The second field plate 261 may be formed on the AlGaN layer 250, and may be separated from the first field plate 261 by a first distance S.

The Schottky electrode 271 and the ohmic electrode 272 may be formed on the AlGaN layer 250. For example, the Schottky electrode 271 may be formed to be in contact with the first field plate 261 on the AlGaN layer 250.

The passivation layer 280 may be formed across the AlGaN layer 250, the first field plate 261, the second field plate 262, the Schottky electrode 271, and the ohmic electrode 272, and may expose a portion of the Schottky electrode 271 and a portion of the ohmic electrode 272. The passivation layer 280 may be formed of an insulating material, for example, aluminum oxide (Al₂O₃), silicon nitride (SiN,), silicon oxide (SiOₓ), and the like.

The first field plate 261, the first space S, and the second field plate 262 may distribute an electric field applied to the Schottky electrode 671 to reduce a leakage current, and to increase a breakdown voltage. When compared to a device in which a transistor may include only a single field plate that is in contact with a gate electrode, the semiconductor device 200 may improve an electric field distribution effect through the second field plate 262, in addition to the first field plate 261, and may also distribute an electric field through the first distance S between the first field plate 261 and the second field plate 262.

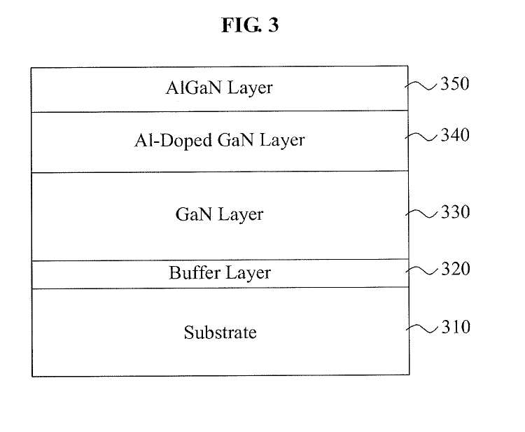

FIGS. 3 through 8 illustrate cross-sectional views of stages in an exemplary method of manufacturing a nitride based heterojunction semiconductor device according to an embodiment. In FIG. 3, a buffer layer 320, a GaN layer 330, an Al-doped GaN layer 340, and an AlGaN layer 350, are sequentially formed on a substrate 310.

The buffer layer 320 may be formed by growing, e.g., at a low temperature ranging from about 500° C. to about 550° C., an AIN or GaN based nitride layer on the substrate 310 used for growing nitrides, for example, a sapphire substrate, a silicon carbide (SiC), a nitride substrate, and the like.

The semi-insulating high resistance GaN layer 300 may be formed by forming, on the buffer layer 320, a Ga vacancy that may act as a deep-level trap by adjusting a grain size. For example, the high resistance GaN layer 330 may be formed to be doped with iron (Fe), carbon (C), magnesium (Mg), zinc (Zn), and the like. When the grain size is formed to be small when the GaN layer 330 is formed, the GaN layer 330 may have a resistance value greater than 1.0×10⁹ ohms per square meter (Ω/m²), e.g., since the semi-insulating high resistance GaN layer 300 may include a great number of edge dislocations.

The Al-doped GaN layer 340 may be formed on the GaN layer 330. The Al-doped GaN layer 340 may improve crystallinity, and may improve an electric property of a Schottky diode. When the Al-doped GaN layer 340 is formed, a content of Al to be applied may be about 0.1% to about 1%.

The AlGaN layer 350 may be formed on the Al-doped GaN layer 340.

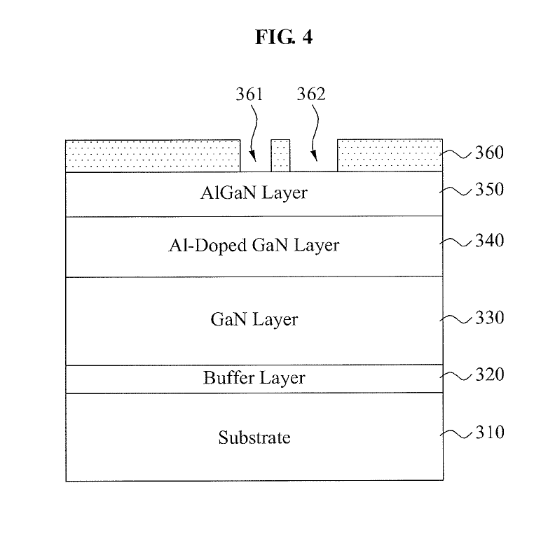

In FIG. 4, an insulating layer 360 is deposited on an AlGaN layer 350, and a first via-hole 361 and a second via-hole 362 (that is separated from the first via-hole 361 by a first distance) are formed on the insulating layer 360.

Referring to FIG. 4, the insulating layer 360 may be deposited on an entire upper portion of the AlGaN layer 350, using, e.g., a SiO₂ material. The first via-hole 361 may be formed by etching an area to form a first field plate. The second via-hole 362 to form a second field plate may be formed by etching an area that is separated from the first via-hole 361 by the first distance. The AlGaN layer 350 may be exposed through the first via-hole 361 and the second through hole 362.

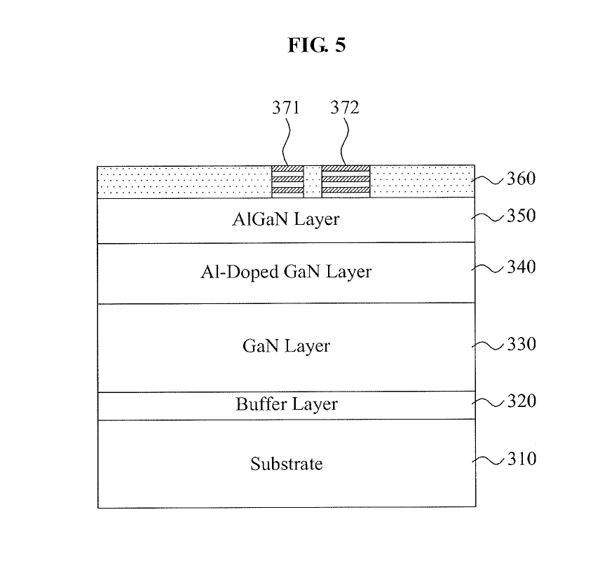

In FIG. 5, a first field plate 371 and a second field plate 372 are formed.

Referring to FIG. 5, the first field plate 371 and the second field plate 372 having superlattice structures may be formed by alternately regrowing a p-type AlGaN layer and a p-type GaN layer on the AlGaN layer 350 exposed through the first via-hole 361 and the second via-hole 362, respectively.

When the first field plate 371 and the second field plate 372 are formed by regrowing the AlGaN layer 350, crystallinity may be improved. Also, since an etching process may not be performed in the process of forming the first field plate 371 and the second field plate 372, a surface damage that may occur in the etching process may be substantially prevented and/or substantially reduced. Accordingly, a leakage current that may be caused by the surface damage may be reduced. That is, by the regrowth of the first field plate 371 and the second field plate 372, a surface of a corresponding area on the AlGaN layer 350 may remain stable.

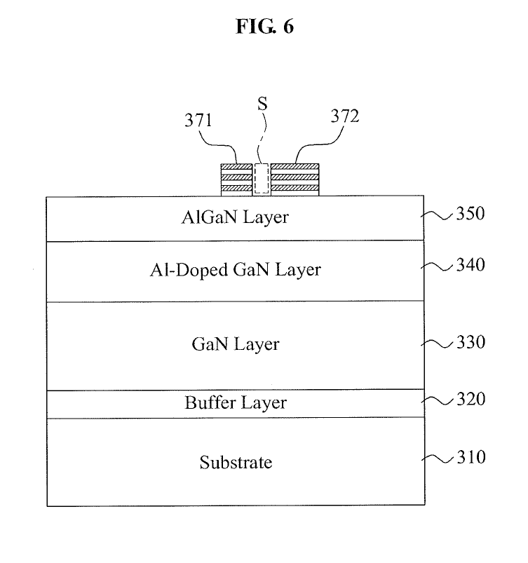

In FIG. 6, the insulating layer 360 is removed from the AlGaN layer 350. As illustrated in FIG. 6, the AlGaN layer 350 may be exposed by etching the insulating layer 360, whereby only the first field plate 371 and the second field plate 372 may be maintained on the AlGaN layer 350. In this instance, the first field plate 371 and the second field plate 372 may be separated from each other by a first distance S.

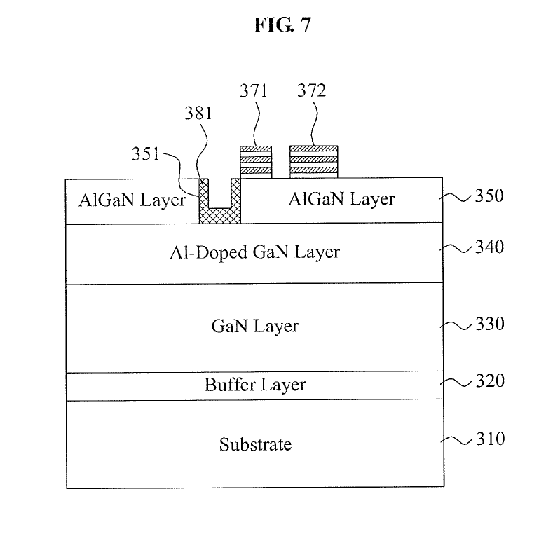

In FIG. 7, an etched area 351 on the AlGaN layer 350 is formed, and a gate insulating layer 381 is formed in the etched area 351. The etched area 351 may be formed where a gate electrode is formed on the AlGaN layer 350. The etched area 351 may be formed so that one side wall of the etched area 351 and one side surface of the first field plate 371 are aligned, thereby bringing a gate electrode and the first field plate 371 into contact with each other. The gate insulating layer 381 may be formed by depositing a SiO₂ material in the etched area 351 after the etched area 351 is formed.

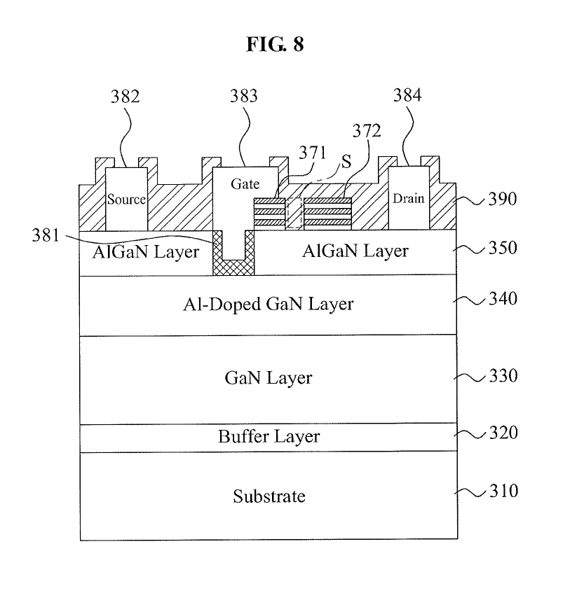

In FIG. 8, a source electrode 382, a gate electrode 383, and a drain electrode 384 are formed on the AlGaN layer 350. The source electrode 382, the gate electrode 383, and the drain electrode 384 may be formed by depositing a metallic material. In this process, the source electrode 382 and the drain electrode 384 may be formed to be separated from the first field plate 371 and the second field plate 372, and the gate electrode 383 may be formed to be in contact with the first field plate 371. The second field plate 372 may be positioned between the first field plate 371 and the drain electrode 384. Through the first field plate 371, the first distance S, and the second field plate 372, an electrode field that may be concentrated on a corner portion of the gate electrode 383 may be distributed, an avalanche effect may be reduced, and a breakdown voltage may be increased.

In this process, a passivation layer 390 may be formed across an entire upper portion of the AlGaN layer 350 to expose portions of the source electrode 382, the gate electrode 383, and the drain electrode 384.

Although the method of manufacturing a nitride based heterojunction field effect transistor has been described with reference to FIGS. 3 through 8, a nitride based heterojunction Schottky diode may be manufactured by a similar method. For example, the similar method may include a process of forming a first field plate and a second field plate by regrowing an AlGaN layer, and may include forming the first field plate to be in contact with a Schottky electrode.

By way of summary and review, a gallium nitride (GaN) material may be used for a power amplifier and may be suitable for, e.g., a high output and high frequency device since the GaN material may have properties of a relatively great energy band gap, a relatively high heat conductivity, and the like, when compared to other materials such as a silicon (Si) material and a gallium arsenide (GaAs) material. A semiconductor device, for example, a AlGaN/GaN heterojunction field effect transistor, may have a high band discontinuity at a junction interface, and a high-density of electrons may be freed in the interface, such that an electron mobility may increase. However, the AlGaN/GaN heterojunction field effect transistor may have an unstable surface state of an AlGaN layer. Accordingly, when a strong electric field is applied to a gate electrode, a weak portion of the AlGaN layer may be destroyed, and it may be difficult to obtain a high reverse breakdown voltage.

According to exemplary embodiments, a nitride based heterojunction semiconductor device and a manufacturing method thereof may include a first field plate and a second field plate, and may distribute an electric field applied to a gate electrode or a Schottky electrode to increase a breakdown electrode.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A nitride based heterojunction semiconductor device, comprising:
a GaN layer on a substrate;
an Al-doped GaN layer on the GaN layer;
an AlGaN layer on the Al-doped GaN layer;
a source electrode, a gate electrode, and a drain electrode on the AlGaN layer;
a first field plate on the AlGaN layer, the first field plate being in contact with the gate electrode; and
a second field plate on the AlGaN layer, the second field plate being separated from the first field plate by a distance.

2. The semiconductor device as claimed in claim 1, wherein the first field plate and the second field plate have a superlattice structure in which a p-type AlGaN layer and a p-type GaN layer are laminated alternately.

3. The semiconductor device as claimed in claim 1, wherein the AlGaN layer includes an etched area at a position in which the gate electrode is located.

4. The semiconductor device as claimed in claim 3, further comprising:
a gate insulating layer between the etched area and the gate electrode.

5. The semiconductor device as claimed in claim 3, wherein a sidewall of the etched area and a sidewall of the first field plate are aligned.

6. The semiconductor device as claimed in claim 1, further comprising:
a passivation layer on the AlGaN layer, the passivation layer exposing the source electrode, the gate electrode, and the drain electrode.

7. The semiconductor device as claimed in claim 1, wherein the GaN layer is a semi-insulating high-resistance GaN layer.

8. The semiconductor device as claimed in claim 1, wherein:
the first field plate is between the AlGaN layer and the gate electrode, and
the second field plate is between the first field plate and the drain electrode.

9. The semiconductor device as claimed in claim 1, wherein a content of Al in the Al-doped GaN layer is less than or equal to about 1 at.%.

10. A nitride based heterojunction semiconductor device, comprising:
a GaN layer on a substrate;
an Al-doped GaN layer on the GaN layer;
an AlGaN layer on the Al-doped GaN layer;
a Schottky electrode and an ohmic electrode on the AlGaN layer;
a first field plate on the AlGaN layer, the first field plate being in contact with the Schottky electrode; and
a second field plate on the AlGaN layer, the second field plate being separated from the first field plate by a distance.

11. The semiconductor device as claimed in claim 10, wherein the first field plate and the second field plate have a superlattice structure in which a p-type AlGaN layer and a p-type GaN layer are laminated alternately.

12. The semiconductor device as claimed in claim 10, wherein:
the first field plate is between the Schottky electrode and the ohmic electrode, and
the second field plate is between the first field plate and the ohmic electrode.

13. A method of manufacturing a nitride based heterojunction semiconductor device, the method comprising:
forming a GaN layer, an Al-doped GaN layer, and an AlGaN layer on a substrate, sequentially;
depositing an insulating layer on the AlGaN layer;
forming, in the insulating layer, a first via-hole and a second via-hole to expose the AlGaN layer, the second via-hole being separated from the first via-hole by a distance;
forming a first field plate and a second field plate on the AlGaN layer that is exposed through the first via-hole and the second via-hole;
removing the insulating layer from the AlGaN layer; and
forming, on the AlGaN layer, a first electrode that is separated from the first field plate and the second field plate, and forming, on the AlGaN layer, a second electrode that is in contact with the first field plate.

14. The method as claimed in claim 13, wherein forming the first field plate and the second field plate includes regrowing the AlGaN layer.

15. The method as claimed in claim 13, wherein the first field plate and the second field plate have a superlattice structure in which a p-type AlGaN layer and a p-type GaN layer are laminated alternately.

16. The method as claimed in claim 13, further comprising forming, on the AlGaN layer, a third electrode that is separated from the first field plate and the second field plate, wherein:
the first electrode is a source electrode,
the second electrode is a gate electrode, and
the third electrode is a drain electrode.

17. The method as claimed in claim 16, further comprising:
forming an etched area on the AlGaN layer; and
forming a gate insulating layer in the etched area.

18. The method as claimed in claim 16, further comprising:
forming, on the AlGaN layer, a passivation layer to expose the source electrode, the gate electrode, and the drain electrode.

19. The method as claimed in claim 16, wherein forming the first via-hole and the second via-hole includes:
forming the first via-hole in a first area in which the gate electrode is to be formed, and
forming the second via-hole between the first via-hole and a second area in which the drain electrode is to be formed.

20. The method as claimed in claim 13, wherein:
the first electrode is an ohmic electrode, and
the second electrode is a Schottky electrode.
